(19) United States
(12) Patent Application Publication
(10) Pub. No.: US 2026/0144030 A1
(43) Pub. Date: May 21, 2026

(54) METHOD OF EXTENDING QUEUE TIME BETWEEN PROCESS STEPS

(71) Applicant: Tokyo Electron Limited, Tokyo (JP)

(72) Inventors: Kandabara Tapily, Albany, NY (US); Kai-Hung Yu, Albany, NY (US)

(21) Appl. No.: 18/955,470

(22) Filed: Nov. 21, 2024

(51) Int. Cl. H01L 21/768

(52) U.S. Cl. CPC H10W 20/041; H10W 20/038

(57) ABSTRACT

In a method of processing a substrate having a copper line in the substrate wherein an Ru metal cap layer is formed on a copper line disposed in the substrate and an ashless carbon oxygen barrier layer is deposited on the Ru metal cap layer to provide a substrate having a protected capped copper line. The substrate having the protected capped copper line is queued before carrying out subsequent process steps, and the ashless carbon oxygen barrier layer is removed before carrying out subsequent process steps. Protecting the capped copper line in this manner provides greater flexibility in managing substrate processing operations by permitting longer queue times before subsequent substrate processing steps are carried out, without fear that the copper line will be adversely affected by oxidation during the queue.

### FIELD

The present invention relates to surface treatment of metal-containing materials in small pitch structures, such as integrated circuit structures.

### BACKGROUND

In the semiconductor industry, increasing circuit density drives progress toward smaller and smaller dimensions and larger numbers of transistors placed in an individual device. Metal features in microelectronic devices include contacts and interconnects (i.e., wiring). Metal features in semiconductor devices can be formed by strategies such as damascene techniques and/or metal patterning techniques. In damascene techniques, trenches and vias are formed in a dielectric material, such as by etching, and then the trenches and vias are filled with metal, such as copper or other metal. Patterning techniques involve patterning metal films to form patterned metal features, typically by etching. In contrast to other dielectric materials, metal materials are more challenging to etch; hence, damascene strategies are often used to form metal interconnects. Damascene techniques include dual damascene, single damascene, and semi-damascene strategies. The “single” damascene process involves creating and filling the trenches (or vias) first and then proceeding to fill the trenches (or vias). Then, the etching and filling is repeated for the vias (or trenches). A “Dual” damascene process forms the trenches and vias at the same time and then fills both the trench and vias at the same time.

A process for protecting low-k layers from damage caused by exposure to atmospheric conditions in BEOL process steps is described in US Patent Publication No. 2019/0393084, where thermal decomposition materials may be utilized to coat exposed regions of the low-k layers so that the low-k layers are not exposed to atmospheric conditions.

### SUMMARY

Interconnect lines in semiconductor wafers often comprise copper, for example, dual damascene copper interconnects disposed between interlayer dielectric materials. As current flows through the copper in the lines, electromigration (“EM”) of copper atoms over time degrades the integrity of the lines as copper migrates in the direction of the electron flow. The electromigration is usually most prevalent in the surface areas of the lines. Various capping solutions have been attempted in the past to address electromigration issues of copper lines, including use of metal cap materials such as tantalum (Ta), cobalt (Co), cobalt tungsten phosphide (CoWP), or ruthenium (Ru) being applied to the top interface for better EM reliability.

It has been found that capping the copper line with a Ru layer is particularly useful to enhance EM reliability, because Ru is a noble metal that exhibits high resistivity. However, Ru is not a good oxygen barrier, particularly at thin scale, and permits oxidation of the Cu upon air break prior to carrying out subsequent substrate processing steps. This Cu oxidation is detrimental to EM lifetime of the ultimate semiconductor device.

It has further been found that oxidation of the Ru metal capped copper line may be substantially reduced or prevented by depositing an ashless carbon oxygen barrier layer on the Ru metal cap layer to provide a protected capped copper line prior to carrying out subsequent process steps. Protecting the capped copper line in this manner provides greater flexibility in managing substrate processing operations by permitting longer queue times before subsequent substrate processing steps are carried out, without fear that the copper line will be adversely affected by oxidation during the queue. The use of ashless carbon as the oxygen barrier layer is particularly advantageous because it can be easily removed when appropriate by methods that do not harm the in-process substrate, such as by thermal treatment or plasma treatment.

### BRIEF DESCRIPTION OF THE DRAWINGS

The accompanying drawings, which are incorporated in and constitute a part of this application, illustrate several aspects of the invention and together with a description of the embodiments explain the principles of the invention. A brief description of the drawings is as follows:

FIG. 1 is a schematic graphical illustration of method of processing a substrate as described herein.

FIG. 2 is a schematic graphical illustration of an alternate method of processing a substrate as described herein.

FIG. 3 is a flowchart illustrating a method of processing a substrate.

### DETAILED DESCRIPTION

The aspects of the present invention described below are not intended to be exhaustive or to limit the invention to the precise forms disclosed in the following detailed description. Rather a purpose of the aspects chosen and described is by way of illustration or example, so that the appreciation and understanding by others skilled in the art of the general principles and practices of the present invention can be facilitated.

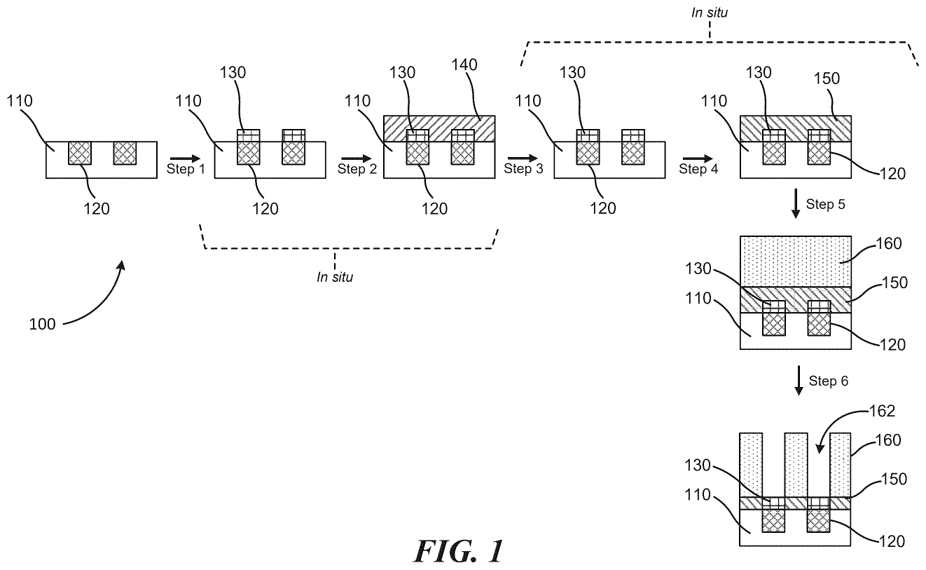

Turning now to the Figures, FIG. 1 is a schematic graphical illustration of a method 100 of processing a substrate 110 having a copper line 120 disposed in the dielectric material of the substrate 110. In an embodiment, substrate 110 having a copper line 120 may be optionally treated to enhance aspects of the copper line or other aspects of the substrate, such as by plasma treatment, annealing, chemical mechanical planarization, and the like. A ruthenium (“Ru”) cap 130 is formed on the copper line 120 in Step 1, for example, by selective deposition of Ru followed by etching to remove excess Ru present on the surface of substrate 110. In an embodiment, copper line 120 is pre-cleaned and/or pretreated prior to deposition of the Ru metal cap 130. In an embodiment, the Ru metal cap 130 is provided as a layer having a thickness of less than 5 nm. In an embodiment, the Ru metal cap layer has a thickness of from 1 nm to 5 nm.

In an embodiment, the Ru metal cap 130 comprises, in addition to Ru, one or more materials selected from the group consisting of Nb, Mo, Ni, NiAl, CuAl, CoSn, and CoSi.

In an embodiment, copper line 120 is provided with a cap of one or more graphene 2D cap layers in addition to the Ru metal cap 130. Examples of such graphene cap layers are described in U.S. Pat. No. 9,472,450, the disclosure of which is incorporated by reference. In an embodiment, the graphene cap layers are selected from single-layer graphene (e.g., nominally 0.34 nm thick), few-layer graphene (e.g., 2-10 graphene layers), multi-layer graphene (e.g., >10 graphene layers), a mixture of single-layer, few-layer, and multi-layer graphene, or any combination of graphene layers mixed with amorphous and/or disordered carbon phases. In an embodiment, the graphene cap layers comprise substitutional (where C atoms in graphene are replaced with dopant atoms covalently bonded to next nearest neighbor, nnn, atoms), and dopant atoms or molecules that do not form covalent bonds to graphene and lie on top of the graphene layer or between graphene layers in the case few layer or multilayer intercalated graphene caps. Graphene caps may be prepared, for example, by a selective deposition process such as chemical vapor deposition (CVD), plasma enhanced chemical vapor deposition (PECVD), or ultraviolet (UV) assisted CVD or solution based deposition. The graphene caps may help reduce the lateral conductivity in the interconnects, since they have very high surface conductivity.

An ashless carbon oxygen barrier layer 140 is then deposited on the Ru metal cap 130 to provide a substrate having a protected capped copper line. For purposes of the present discussion, “ashless carbon” is a material that decomposes in the presence of heat and air to water and carbon dioxide.

In an embodiment, the ashless carbon oxygen barrier layer 140 is deposited in situ in Step 2 in the same processing station used for forming the Ru metal cap 130 on the copper line 120.

In an embodiment, the ashless carbon oxygen barrier layer 140 is deposited by a plasma deposition process. In an embodiment, the ashless carbon oxygen barrier layer is deposited by a deposition process selected from physical vapor deposition (PVD), chemical vapor deposition (CVD), electrodeposition (ED), and atomic layer deposition (ALD).

In an embodiment, the ashless carbon oxygen barrier layer 140 comprises a heat depolymerized material layer or carbon black. In an embodiment, the ashless carbon oxygen barrier layer is prepared from a polymer which is formed by polymerizing at least two different reactants (e.g., monomers), that is then depolymerized by heat, such as described in U.S. Pat. No. 11,282,920, the disclosure of which is incorporated by reference herein. In an embodiment, the ashless carbon oxygen barrier layer is a heat depolymerized material layer prepared from a polymer selected from polyamide, nylon, polyester, and polycarbonate.

In an embodiment, the ashless carbon oxygen barrier layer 140 has a thickness of from about 1 nm to about 30 nm.

The substrate is queued for a time as appropriate for the specific process being performed. Queueing may be employed as a purposeful process step as an “air break” to improve properties of certain materials located elsewhere on the substrate. Alternatively, queueing may be an unavoidable event necessitated by delay in access to a processing platform having a limited throughput or other availability issue in the ordinary process flow of a production hardware array. In many conventional processes where queueing occurs for one reason or another, the acceptable queue time for uncapped Cu may be less than 2 hours. For purposes of the present discussion, the time from protection of the protected capped copper line to the step of removing the ashless carbon oxygen barrier layer is the queue time (“QT”). In an embodiment of the present method, the substrate having a protected capped copper line is queued for a queue time of greater than two hours before removing the ashless carbon oxygen barrier layer. In an embodiment of the present method, the substrate having a protected capped copper line is queued for a time greater than four hours before removing the ashless carbon oxygen barrier layer. In an embodiment of the present method, the substrate having a protected capped copper line is queued for a time of greater than six hours before removing the ashless carbon oxygen barrier layer. In an embodiment of the present method, the substrate having a protected capped copper line is queued for a time of greater than two hours and less than 12 hours before removing the ashless carbon oxygen barrier layer. In an embodiment of the present method, the substrate having a protected capped copper line is queued for a time of greater than four hours and less than 12 hours before removing the ashless carbon oxygen barrier layer. In an embodiment of the present method, the substrate having a protected capped copper line is queued for a time of greater than six hours and less than 12 hours before removing the ashless carbon oxygen barrier layer.

For purposes of the present discussion, the total amount of time that the Ru capped copper line is unprotected is the time after formation of the Ru cap on the copper line and initiation of the carrying out of subsequent process steps where there is no protective ashless carbon oxygen barrier layer in place. Thus, the total amount of time that the Ru capped copper line is unprotected is the sum of:
a) the unprotected time (“UT1”) that is between the forming of the Ru metal cap layer on the copper line disposed in the substrate and the depositing of the ashless carbon oxygen barrier layer on the Ru metal cap layer
   and
b) the unprotected time (“UT2”) between the removal of the ashless carbon oxygen barrier layer and initiation of the carrying out of subsequent process steps.

In an embodiment, the total amount of time that the Ru capped copper line is unprotected is less than two hours. n an embodiment, the total amount of time that the Ru capped copper line is unprotected is less than an hour and a half.

After queueing, the ashless carbon oxygen barrier layer 140 is removed from the substrate in Step 3, making the substrate available for carrying out further process steps, such as applying an etch stop layer 150. In an embodiment, the ashless carbon oxygen barrier layer is removed by thermal treatment. When the method is carried out as part of BEOL processes, the thermal treatment is preferably carried out at temperature below 400° C. In an embodiment, the ashless carbon oxygen barrier layer is removed by plasma treatment. In an embodiment, the ashless carbon oxygen barrier layer is removed by plasma treatment with energized species, such as O₂, H₂/N₂.

In an embodiment, the ashless carbon oxygen barrier layer is removed in situ in the same processing station used for the next of the further process steps, such as depositing an etch stop layer 150 in Step 4. Carrying out the step of removal of the ashless carbon oxygen barrier layer on the same platform as the next step advantageously avoids the need to utilize a separate processing station for the ashless carbon oxygen barrier layer removal step, which would increase equipment costs and plant floorspace required. Additionally, carrying out the step of removal of the ashless carbon oxygen barrier layer on the same platform as the next step avoids the need to transport the now unprotected Ru capped copper line from one platform to the next, which increases the unprotected time and introduces a potential opportunity for equipment error or other event causing adverse extension of the time period in which the Ru capped copper line is unprotected.

In an embodiment, the process step immediately following removal of the ashless carbon oxygen barrier layer is application of an etch stop layer (ESL), such SiCN, SiN, Al₂O₃, and the like. This is particularly the case when the structure being prepared is an interconnect.

In an embodiment, the etch stop layer may be formed from a material such as silicon oxycarbonitride (SiOCN), silicon oxynitride (SiOₓN_{y}), silicon nitride (Si₃N₄; SiN), carbon doped silicon nitride (SiCN), silicon oxide (SiO₂), silicon carbide (SiC), boron nitride (BN) or aluminum oxynitride (AlOₓC_{y}N_{z}.

Subsequent patterning steps can be carried out, for example, by providing a low-k dielectric material 160 on top of etch stop layer 150 in Step 5 and removing portions thereof to provide recesses 162 for filling with interconnect materials in Step 6.

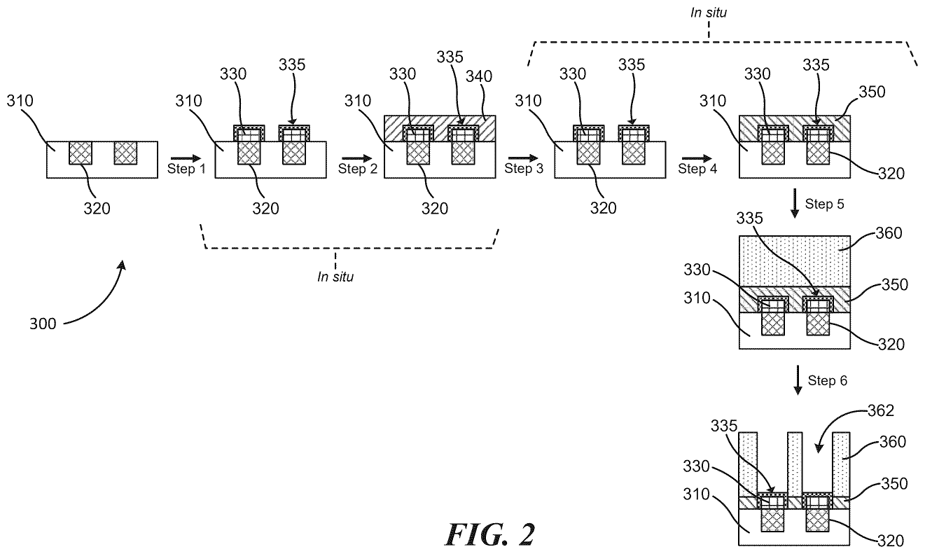

FIG. 2 is a schematic graphical illustration of an alternate method of processing a substrate 300 of processing a substrate 310 having a copper line 320 disposed in the dielectric material of the substrate 310. In an embodiment, substrate 310 having a copper line 320 may be optionally treated to enhance aspects of the copper line or other aspects of the substrate, such as by plasma treatment, annealing, chemical mechanical planarization, and the like. A ruthenium (“Ru”) metal cap 330 is formed on the copper line 320 in Step 1, for example, by selective deposition of Ru followed by etching to remove excess Ru present on the surface of substrate 310. The Ru metal cap 330 is additionally provided with a graphene cap 335 (for example, Graphene) as an added electromigration or diffusion barrier on Ru metal cap 330. In an embodiment, graphene cap 335 is provided on the top surface of Ru metal cap 330. In an embodiment, graphene cap 335 is provided on the top surface of Ru metal cap 330 and additionally on any otherwise exposed surfaces of Ru metal cap 330, such as side wall surfaces as shown in FIG. 2.

The method as shown in FIG. 2 then proceeds in much the same way as shown in FIG. 1, wherein the ashless carbon oxygen barrier layer 340 is deposited on the combined structure of the graphene cap 335 and Ru metal cap 330 in Step 2 to provide a substrate having a protected capped copper line. Subsequent steps 3-6 proceed as described above, where ashless carbon oxygen barrier layer 340 is removed and further process steps, such as depositing an etch stop layer 350 in Step 4 is carried out. Subsequent patterning steps can be carried out, for example, by providing a low-k dielectric material 360 on top of etch stop layer 350 in Step 5 and removing portions thereof to provide recesses 362 for filling with interconnect materials in Step 6.

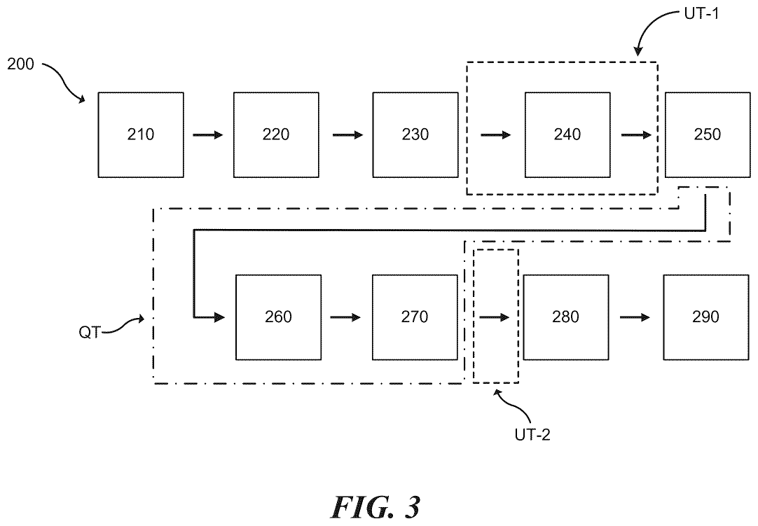

FIG. 3 is a flowchart illustrating a method of 200 processing a substrate, wherein as a first step 210 an incoming wafer with copper line is provided for processing. In optional second step 220, the wafer and/or the copper line may be treated to enhance aspects of the copper line or other aspects of the substrate, such as by plasma treatment, annealing, chemical mechanical planarization, and the like.

An Ru cap is formed on the copper line in step 230. Optionally, the wafer and/or the Ru cap may be treated to enhance aspects of the Ru cap or other aspects of the substrate, such as by plasma treatment, annealing, chemical mechanical planarization, laser treatment and the like in step 240.

In step 250, an ashless carbon oxygen barrier layer is deposited on the Ru metal cap to provide a substrate having a protected capped copper line.

In step 260, the substrate is queued for a time as appropriate for the specific process being performed. As noted above, the queueing step may be carried out as part of the ordinary process flow of a production hardware array, or may be an air break that is a functional reaction step as part of the device preparation process.

The ashless carbon oxygen barrier layer is then removed from the substrate in step 270, which is preferably carried out in situ in the same processing station used for the next of the further process steps, such as depositing an etch stop layer as step 280. The use of the same processing station for both steps has been found to both increase efficiency of the process both in avoidance of a transfer step and also in reduction of the footprint of the hardware setup for carrying out the process. Additionally, the use of the same processing station for both steps has been found to reduce the likelihood of introduction of contaminants in the process.

Subsequent patterning steps may then be carried to complete preparation of the device, as represented collectively in step 290.

As discussed above, the time from protection of the protected capped copper line to the step of removing the ashless carbon oxygen barrier layer is the queue time, which is identified as box QT on FIG. 2. The unprotected time “UT1 as discussed above that is between the forming of the Ru metal cap layer on the copper line disposed in the substrate and the depositing of the ashless carbon oxygen barrier layer on the Ru metal cap layer is identified as box UT1 on FIG. 2. The unprotected time UT2 as discussed above that is the time between the removal of the ashless carbon oxygen barrier layer and initiation of the carrying out of subsequent process steps is identified as box UT2 on FIG. 2.

As used herein, the terms “about” or “approximately” mean within an acceptable range for the particular parameter specified as determined by one of ordinary skill in the art, which will depend in part on how the value is measured or determined, e.g., the limitations of the sample preparation and measurement system. Examples of such limitations include preparing the sample in a wet versus a dry environment, different instruments, variations in sample height, and differing requirements in signal-to-noise ratios. For example, “about” can mean greater or lesser than the value or range of values stated by 1/10 of the stated values, but is not intended to limit any value or range of values to only this broader definition. For instance, a concentration value of 30% means a concentration between 27% and 33%. Each value or range of values preceded by the term “about” is also intended to encompass the embodiment of the stated absolute value or range of values. Alternatively, particularly with respect to biological systems or processes, the term can mean within an order of magnitude, preferably within 5-fold, and more preferably within 2-fold, of a value.

Throughout this specification and claims, unless the context requires otherwise, the word “comprise”, and variations such as “comprises” and “comprising”, will be understood to imply the inclusion of a stated integer or step or group of integers or steps but not the exclusion of any other integer or step or group of integer or step. When used herein “consisting of” excludes any element, step, or ingredient not specified in the claim element. When used herein, “consisting essentially of” does not exclude materials or steps that do not materially affect the basic and novel characteristics of the claim. In the present disclosure of various embodiments, any of the terms “comprising”, “consisting essentially of” and “consisting of” used in the description of an embodiment may be replaced with either of the other two terms.

All patents, patent applications (including provisional applications), and publications cited herein are incorporated by reference as if individually incorporated for all purposes. Unless otherwise indicated, all parts and percentages are by weight and all molecular weights are weight average molecular weights. The foregoing detailed description has been given for clarity of understanding only. No unnecessary limitations are to be understood therefrom. The invention is not limited to the exact details shown and described, for variations obvious to one skilled in the art will be included within the invention defined by the claims.

1. A method of processing a substrate so as to extend a queue time between process steps, the method comprising:
forming an Ru metal cap layer on a copper line disposed in a substrate;
depositing an ashless carbon oxygen barrier layer on the Ru metal cap layer to provide a substrate having a protected capped copper line;
queueing the substrate having a protected capped copper line before carrying out subsequent process steps;
removing the ashless carbon oxygen barrier layer; and
carrying out subsequent process steps.

2. The method of claim 1, wherein the Ru metal cap layer has a thickness of less than 5 nm; or wherein the Ru metal cap layer has a thickness of from 1 nm to 5 nm.

3. The method of claim 1, wherein the Ru metal cap layer is formed on the copper line by a selective deposition process.

4. The method of claim 1, wherein the ashless carbon oxygen barrier layer is deposited by plasma deposition process.

5. The method of claim 1, wherein the ashless carbon oxygen barrier layer is deposited by a deposition process selected from physical vapor deposition (PVD), chemical vapor deposition (CVD), electrodeposition (ED), and atomic layer deposition (ALD).

6. The method of claim 1, wherein the ashless carbon oxygen barrier layer comprises a heat depolymerized material layer or carbon black.

7. The method of claim 1, wherein the ashless carbon oxygen barrier layer is a heat depolymerized material layer prepared from a polymer selected from polyamide, nylon, polyester, and polycarbonate.

8. The method of claim 1, wherein the ashless carbon oxygen barrier layer has a thickness of from about 1 nm to about 30 nm.

9. The method of claim 1, wherein the ashless carbon oxygen barrier layer is deposited in situ in the same processing station used for forming the Ru cap on the copper line.

10. The method of claim 1, wherein the substrate having a protected capped copper line is queued for a time of greater than four hours before removing the ashless carbon oxygen barrier layer; or wherein the substrate having a protected capped copper line is queued for a time of greater than six hours before removing the ashless carbon oxygen barrier layer.

11. The method of claim 1, wherein the substrate having a protected capped copper line is queued for a time of greater than two hours and less than 12 hours before removing the ashless carbon oxygen barrier layer; or wherein the substrate having a protected capped copper line is queued for a time of greater than four hours and less than 12 hours before removing the ashless carbon oxygen barrier layer; or wherein the substrate having a protected capped copper line is queued for a time of greater than six hours and less than 12 hours before removing the ashless carbon oxygen barrier layer.

12. The method of claim 1, wherein the total amount of time that the Ru capped copper line is unprotected is less than two hours; or wherein the total amount of time that the Ru capped copper line is unprotected is less than an hour and half.

13. The method of claim 1, wherein the ashless carbon oxygen barrier layer is removed by thermal treatment; or wherein the ashless carbon oxygen barrier layer is removed by plasma treatment.

14. The method of claim 1, wherein the ashless carbon oxygen barrier layer is removed in situ in the same processing station used for the next of the subsequent process steps.

15. The method of claim 1, wherein the subsequent process steps comprises applying an etch stop layer.

16. The method of claim 1, wherein the process step immediately following removal of the ashless carbon oxygen barrier layer is application of an etch stop layer.

17. The method of claim 1, wherein the metal cap comprises, in addition to Ru, one or more materials selected from the group consisting of Nb, Mo, Ni, NiAl, CuAl, CoSn, CoSi and 2D materials.

18. The method of claim 1, wherein the copper line is provided with an added electromigration or diffusion barrier cap on the Ru metal cap.

19. The method of claim 18, wherein the added electromigration or diffusion barrier cap comprises one or more graphene cap layers.

20. The method of claim 19, wherein the graphene cap layers are selected from single-layer graphene, few-layer graphene, multi-layer graphene, a mixture of single-layer, few-layer, and multi-layer graphene, or any combination of graphene layers optionally mixed with amorphous and/or disordered carbon phases.
